(19) United States
(12) Patent Application Publication
(10) Pub. No.: US 2006/0257690 A1
(43) Pub. Date: Nov. 16, 2006

(54) Coated cutting tool insert

(75) Inventor: Carl Bjormander, Spagna (SE)

Correspondence Address: DRINKER BIDDLE & REATH (DC), 1500 K STREET, N.W., SUITE 1100, WASHINGTON, DC, 20005-1209, US

(73) Assignee: Sandvik Intellectual Property AB

(21) Appl. No.: 11/403,206

(22) Filed: Apr. 13, 2006

(30) Foreign Application Priority Data
Apr. 18, 2005 (SE) 0500858-6

(51) Int. Cl. C23C 16/00; B32B 9/00

(52) U.S. Cl. 428/698; 428/701; 427/249.1; 427/249.19

(57) ABSTRACT

A method for making a coated cutting tool insert by depositing by CVD, onto a cemented carbide, titanium based or ceramic substrate a hard layer system, having a total thickness of from about 2 to about 50 μm, comprising at least one layer selected from titanium carbide, titanium nitride, titanium carbonitride, titanium carboxide and aluminum oxide, and an outer, from about 1 to about 15 μm thick, aluminum oxide layer or (Al₂O₃+ZrO₂)*N multilayer, a penultimate outermost layer of TiOₓ, where x ranges from about 1 to about 2, and an outermost, from about 0.3 to about 2 μm thick, TiCₓN_{y}O_{z} layer, where x+y+z=1, x≧0, y≧0, and z≧0, followed by a post-treatment removing at least said outermost layer on the edge-line and on the rake face.

### BACKGROUND

The present invention relates to a coated cutting tool, suitable for chip forming machining of metals, and a method for producing the same. According to the present invention, there is provided a reliable method for removing coating layers on selected faces of a cutting insert during coating post-treatment.

Modem high productivity chip forming machining of metals requires reliable tools with excellent wear properties. This is achieved by employing a cemented carbide tool body coated with a wear resistant coating, of single layer or multilayer type, most commonly comprising wear layers of TiC, TiN, TiCN and Al₂O₃. For depositing the different layers onto the cemented carbide body, CVD, PVD, or similar coating techniques are used.

EP-A-693574 describes how different parts of a tool are subject to different types of wear during a machining operation. Since the various coating layers have different abilities to withstand the different types of wear, it is suggested to have an outermost Al₂O₃layer on the rake face, because of its ability to withstand diffusion type wear, and on the clearance side it is suggested to have an outermost MeCₓN_{y}O_{z} type layer, where Me is a metal selected from groups IVB, VB, VIB of the periodic table, because of its high resistance to flank wear. A top layer of TiCₓN_{y}O_{z} or, in particular, a goldish TiN, ZrN or HfN top layer also makes it easy to differentiate between a used and an unused cutting edge by the naked eye. Hence, the TiCₓN_{y}O_{z} layer is mechanically removed from either only the edge line or from both the rake face and the edge line to expose the Al₂O₃layer. Normally this is done by a post-treatment such as blasting or brushing of the coated inserts.

During the post-treatment, it is important not to reduce the Al₂O₃ layer thickness along the edge line. The method must therefore be so gentle that only the top TiCₓN_{y}O_{z} layer is removed, leaving the Al₂O₃at the edge line as untouched as possible. However, the described post-treatment method is unreliable as residues of TiCₓN_{y}O_{z} occasionally appear on the Al₂O₃surface after blasting process. TiCₓN_{y}O_{z} residues on the Al₂O₃surface reduce the flaking resistance, due to welding of TiCₓN_{y}O_{z} to the work piece at the cutting edge resulting in coating withdrawal and a lower lifetime of the insert. A second effect of these residues after blasting is the discoloration, visible to the naked eye, of the Al₂O₃surface. In production, blasting is usually repeated or modified in order to remove residual TiCₓN_{y}O_{z}, but this often results in damage, such as flaking of the coating at the cutting edge line. It is therefore important to find a solution to this problem, especially for thin Al₂O₃ coatings, where usually lower blasting pressures are used in order not to damage the coating at the cutting edge, thus being subject to a higher risk of having TiCₓN_{y}O_{z} residues after the blasting process.

In U.S. Pat. No. 6,426,137, a titanium oxide layer is utilized in order to reduce smearing onto the cutting edge. In this case the titanium oxide layer is fully covering the Al₂O₃ surface, acting as the top layer with a thickness of 0.1-3 μm. In another embodiment the titanium oxide layer is coated with a TiN layer.

### OBJECTS AND SUMMARY OF THE INTENTION

It is an object of the present invention to solve the problem of residual TiCₓN_{y}O_{z} on the post-treated edge line and rake face.

In accordance with the invention there is provided a method for making a coated cutting tool insert having an upper face (rake face), an opposite face and at least one clearance face intersecting said upper and opposite faces to define cutting edges comprising depositing by CVD, onto a cemented carbide, titanium based or ceramic substrate
a hard layer system, having a total thickness of about from about 2 to about 50 μm, comprising at least one layer selected from titanium carbide, titanium nitride, titanium carbonitride, titanium carboxide and aluminum oxide, and an outer, from about 1 to about 15 μm thick, aluminum oxide layer or (Al₂O₃+ZrO₂)*N multilayer,
a penultimate outermost layer of TiOₓ, where x ranges from about 1 to about 2 and
an outermost, from about 0.3 to about 2 μm thick, TiCₓN_{y}O_{z} layer, where x+y+z=1, x≧0, y≧0, and z≧0,

by a post-treatment removing at least said outermost layer on the edge-line and on the rake face.

### BRIEF DESCRIPTION OF THE FIGURES

Figs. 1A-1C are light microscope micrographs showing in 200×, the outermost Al₂O₃ layer of inserts according to the present invention, with various amounts of titanium nitride residues after the blasting process, in which in FIG. 1A

A—TiN residues, and

B—Al₂O₃.

FIGS. 2A-2C are scanning electron microscope micrographs showing in 500×, the outermost Al₂O₃ layer of inserts according to the present invention, with various amounts of titanium oxide residues after the blasting process, in which in FIG. 2A

A—Ti₂O₃ residues, and

B—Al₂O₃.

FIG. 3 is a light microscope micrograph showing in 200×, the outermost Al₂O₃ layer of an insert edge according to the prior art, with titanium nitride residues after the blasting process, in which

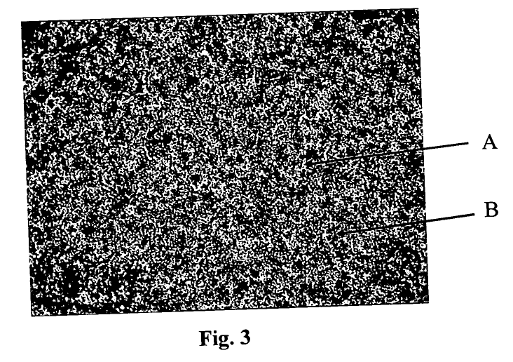

A—TiN residues, and

B—Al₂O₃.

### DETAILED DESCRIPTION OF THE PREFERRED EMBODIMENTS OF THE INVENTION

According to the present invention, there is now provided a method of making a coated cutting tool insert, having an upper face (rake face), an opposite face and at least one clearance face intersecting said upper and opposite faces to define cutting edges, comprising depositing onto a cemented carbide, titanium based or ceramic substrate, using known CVD methods
a hard layer system, having a total thickness of from about 2 to about 50 μm, comprising least one layer selected from titanium carbide, titanium nitride, titanium carbonitride, titanium carboxide and aluminum oxide, and an outer, from about 1 to about 15 μm thick, aluminum oxide layer or (Al₂O₃+ZrO₂)*N multilayer,
a penultimate outermost layer of TiOₓ, where x ranges from about 1 to about 2, preferably from about 1.3 to about 1.9, having a thickness preferably from about 0.05 to about 3 μm, most preferably from about 0.1 to about 1.0 μm, and
an outermost, from about 0.3 to about 2 μm thick, TiCₓN_{y}O_{z} layer, where x+y+z=1, x≧0, y≧0, and z≧0, preferably a single layer or multilayer of TiN, TiC or TiCₓN_{y}, where x+y=1, x≧0 and y≧0,

followed by a post-treatment, preferably blasting or brushing, removing at least said outermost layer on the edge-line and on the rake face. To ensure the performance of the insert and the absence of any discoloration due to TiN residues, it is preferred that said post-treatment also removes at least 50% of the TiOₓ layer, in terms of surface coverage, i.e., preferably at least 50% of the outer layer surface of said hard layer system is exposed.

Using TiOₓ, which has a hardness of about 20% of that of Al₂O₃ with the proposed thickness, the TiCₓN_{y}O_{z} layer is thus lifted up above the rough Al₂O₃ surface, so that it can be fully removed by the blasting media. TiOₓ is furthermore a transparent oxide, which means that any residues left on the Al₂O₃surface are not visible to the naked eye, as is the case with, e.g., TiN.

The present invention also relates to a coated cutting tool insert having an upper face (rake face), an opposite face and at least one clearance face intersecting said upper and opposite faces to define cutting edges made of cemented carbide, titanium based carbonitride or ceramics. The insert is coated with a hard layer system, having a total thickness of from about 2 to about 50 μm, comprising at least one layer selected from titanium carbide, titanium nitride, titanium carbonitride, titanium carboxide and aluminum oxide, and an outer, from about 1 to about 15 μm thick, aluminum oxide, preferably fine grained of a grain size of from about 0.50 to about 3 μm, α-Al₂O₃, layer or (Al₂O₃+ZrO₂)*N multilayer, said hard layer system is provided with a TiOₓ layer, where x ranges from about 1 to about 2, preferably from about 1.3 to about 1.9, with a thickness of preferably from about 0.05 to about 3 μm, most preferably 0.1-1.0 μm, said TiOₓ layer being the outermost layer on the cutting edge line and rake face, and said TiOₓ layer is on the clearance side provided with an outermost, 0.3-2 μm thick, TiCₓN_{y}O_{z} layer, where x+y+z=1, x≧0, y≧0, and z≧0, preferably a single layer or multilayer of TiN, TiC or TiCₓN_{y}, where x+y=1, x≧0 and y≧0.

The grain size of the Al₂O₃ layer is determined from a SEM top view micrograph at 5,000 X magnification of the as deposited Al₂O₃ layer surface. Drawing three straight lines in random directions, the average distances between grain boundaries along the lines, are taken as a measure of the grain size.

In a preferred embodiment said TiOₓ layer on the edge-line and rake face covers less than 50% of the surface of said hard layer system.

The invention is additionally illustrated in connection with the following examples, which are to be considered as illustrative of the present invention. It should be understood, however, that the invention is not limited to the specific details of the examples.

### EXAMPLE 1

A (invention): Cemented carbide cutting inserts CNMG 120408-PM with the composition 5.5 wt-% Co, 8.6 wt-% cubic carbides (TiC+TaC+NbC) and balance WC were coated with CVD-technique according to the following sequence: 0.7 μm TiN, 4.0 μm Ti(CN), 5.0 μm α-Al₂O₃, 0.7 μm titanium oxide (Ti₂O₃) and 0.7 μm TiN.

The Ti₂O₃ layer was deposited by CVD technique, where the substrates to be coated were held at a temperature of 1010° C. and were brought in contact with a hydrogen carrier gas containing TiCl_{4,} CO₂ and HCl. The nucleation was started up in a sequence where the reactant gases HCl and CO₂ entered the reactor first, in an H₂ atmosphere, followed by the TiCl₄. The titanium oxide layer was deposited with a CVD process with the following process parameters:

| Gasflows (in %). T = 1010° C., P = 55 mbar. | Ti₂O₃ |
|---|---|
| H₂ (%) | 88.0 |
| HCl (%) | 7.6 |
| CO₂ (%) | 2.1 |
| TiCl₄ (%) | 2.3 |
| Deposition Rate (μm/hrs) | 1.5 |

The other layers where deposited by known CVD methods.

The coated inserts were post-treated by blasting at the different blasting pressures 1.8, 2.0 and 2.2 bar, using Al₂O₃ grits.

B (prior art): Cemented carbide cutting inserts CNMG 120408-PM with the composition 5.5 wt-% Co, 8.6 wt-% cubic carbides (TiC+TaC+NbC) and balance WC were coated with CVD-technique according to the following sequence: 0.7 μm TiN, 4.0 μm Ti(CN), 5.0 μm α-Al₂O₃ and 0.7 μm TiN by known CVD methods.

The coated inserts were post treated by blasting at 2.4 bar by using Al₂O₃ grits.

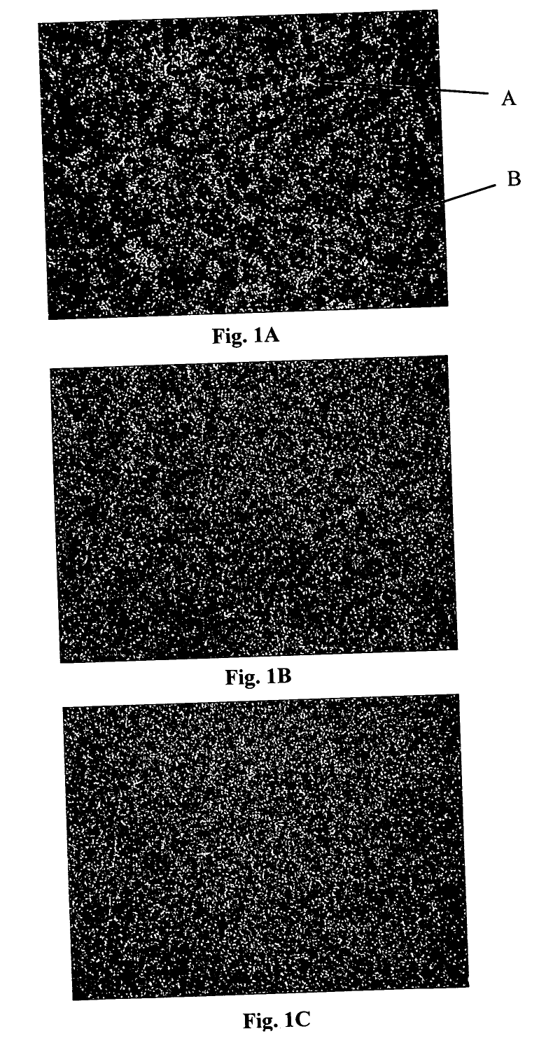

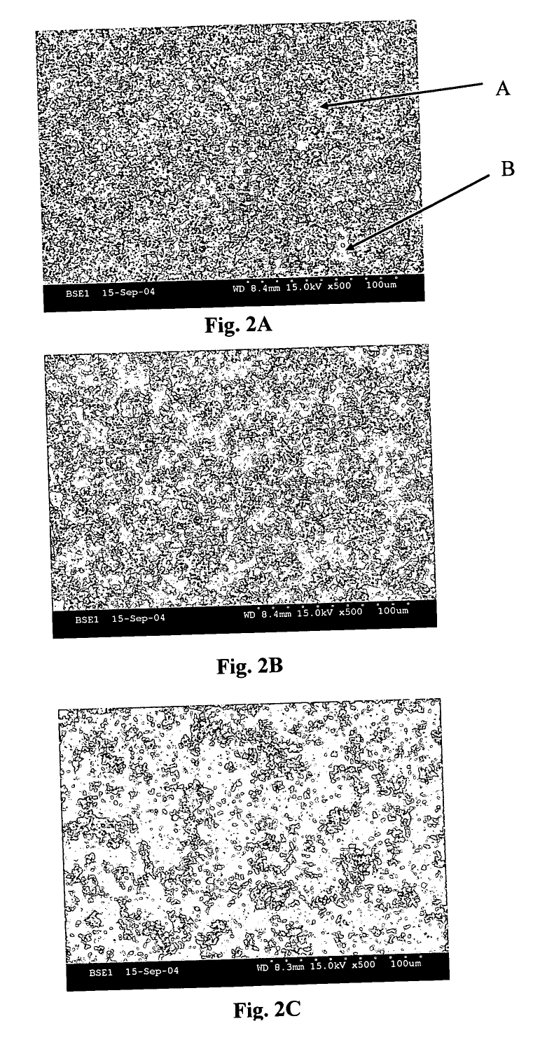

Inserts of type A and B were studied in a light microscope (200×) to detect any TiN residues on the Al₂O₃ surface and further in a scanning electron microscope (500×) to detect residues of Ti₂O₃. The amount of residual Ti₂O₃ was determined using image analysis (Leica Quantimet 500). The results are summarized in the following table.

| | | |
|---|---|---|
| Sample A, blasting | Some amount of TiN residues | <75% of Al₂O₃- |
| at 1.8 bar | on the Al₂O₃-surface as | surface covered |
| (invention) | observed by light microscope | by residual Ti₂O₃ |
| | (FIG. 1A). Insert surface | (FIG. 2A). |
| | appear lightly discolored | |
| | to the naked eye. | |
| Sample A, blasting | <1% of Al₂O₃-surface covered | <50% of Al₂O₃- |
| at 2.0 bar | by residual TiN (FIG. 1B). | surface covered |
| (invention) | No discoloration of the | by residual Ti₂O₃. |
| | insert surface. | (FIG. 2B) |
| Sample A, blasting | No residues of TiN (FIG. 1C). | <30% of Al₂O₃- |
| at 2.2 bar, | No discoloration of the | surface covered |
| (invention) | insert surface. | by residual Ti₂O₃. |
| | | (FIG. 2C) |
| Sample B, blasting | Large amount of TiN residues | |
| at 2.4 bar | on the Al₂O₃-surface as | |
| (prior art) | observed by light microscope | |
| | (FIG. 2). Insert surface | |
| | appear discolored to the | |
| | naked eye. | |

Although the present invention has been described in connection with preferred embodiments thereof, it will be appreciated by those skilled in the art that additions, deletions, modifications, and substitutions not specifically described may be made without departing from the spirit and scope of the inventions as defined in the appended claims.

1. A method for making a coated cutting tool insert having an upper face (rake face), an opposite face and at least one clearance face intersecting said upper and opposite faces to define cutting edges comprising depositing by CVD, onto a cemented carbide, titanium based or ceramic substrate
a hard layer system, having a total thickness of from about 2 to about 50 μm, comprising at least one layer selected from titanium carbide, titanium nitride, titanium carbonitride, titanium carboxide and aluminum oxide, and an outer, from about 1 to about 15 μm thick, aluminum oxide layer or (Al₂O₃+ZrO₂)*N multilayer,
a penultimate outermost layer of TiOₓ, where x ranges from about 1 to about 2 and
an outermost, from about 0.3 to about 2 μm thick, TiCₓN_{y}O_{z} , layer, where x+y+z=1, x≧0, y≧0, and z≧0,
followed by a post-treatment removing at least said outermost layer on the edge-line and on the rake face.

2. A method for making a coated cutting tool insert of claim 1 wherein said post-treatment also removes at least 50% of the TiOₓ layer, in terms of surface coverage.

3. A method for making a coated cutting tool insert of claim 1 wherein the deposited TiOₓ layer thickness is from about 0.05 to about 3 μm.

4. A method for making a coated cutting tool insert of claim 1 wherein in said penultimate outermost layer of TiOₓ, x is from about 1.3 to about 1.9.

5. A method for making a coated cutting tool insert of claim 1 wherein said post-treatment is blasting or brushing.

6. A method for making a coated cutting tool insert of claim 1 wherein the outermost layer is a single layer or multilayer of TiN, TiC or TiCₓN_{y}, where x+y=1, x≧0 and y≧0.

7. A coated cutting tool insert having an upper face (rake face), an opposite face and at least one clearance face intersecting said upper and opposite faces to define cutting edges, made of cemented carbide, titanium based carbonitride or ceramics and coated with a hard layer system, having a total thickness of from about 2 to about 50 μm, comprising at least one layer selected from titanium carbide, titanium nitride, titanium carbonitride, titanium carboxide and aluminum oxide, and an outer, from about 1 to about 15 μm thick, aluminum oxide, preferably fine grained α-Al₂O₃, layer or (Al₂O₃+ZrO₂)*N multilayer, said hard layer system being provided with a TiOₓ layer, where x ranges from about 1 to about 2, said TiOₓ layer being the outermost layer on the cutting edge line and rake face, and said TiOₓ layer is on the clearance side provided with an outermost, from about 0.3 to about 2 μm thick, TiCₓN_{y}O_{z} layer, where x+y+z=1, x≧0, y≧0, and z≧0.

8. A cutting tool insert of claim 7 wherein said TiOₓ layer on the edge-line and rake face covers less than 50% of the surface of said hard layer system.

9. A cutting tool insert of claim 7 wherein said TiOₓ layer has a thickness of from about 0.05 to about 3 μm.

10. A cutting tool insert of claim 7 wherein said TiCₓN_{y}O_{z} layer is a single or multilayer of TiN, TiC or TiCₓN_{y} where x+y=1, x≧0 and y≧0.

11. A cutting tool insert of claim 7 wherein said outer layer is an aluminum oxide.

12. A cutting tool insert of claim 11 wherein said aluminum oxide is a fine grained α-Al₂O₃ layer.
